(19) United States
(12) Patent Application Publication
(10) Pub. No.: US 2009/0319860 A1
(43) Pub. Date: Dec. 24, 2009

(54) OVERCOMING LDPC TRAPPING SETS BY DECODER RESET

(75) Inventors: Eran SHARON, Rishon Lezion (IL); Idan ALROD, Herzliya (IL); Simon LITSYN, Giv'at Shmuel (IL)

Correspondence Address: MARK M. FRIEDMAN, C/O DISCOVEY DISPATCH , 9003 FLIRIN WAY, UPPER MARLBORO, MD, 20772, US

(73) Assignee: Ramot At Tel Aviv University Ltd., Tel Aviv (IL)

(21) Appl. No.: 12/469,790

(22) Filed: May 21, 2009

Related U.S. Application Data
(60) Provisional application No. 61/074,701, filed on Jun. 23, 2008.

(51) Int. Cl. H03M 13/00; G06F 12/02; G06F 12/00

(52) U.S. Cl. 714/752; 711/154; 711/E12.002

(57) ABSTRACT

To decode, in a plurality of iterations, a representation, imported from a channel, of a codeword that encodes K information bits as N>K codeword bits, estimates of the codeword bits are updated by exchanging messages between N bit nodes and N−K check nodes of a graph. If the decoding has failed to converge according to a predetermined failure criterion and if the codeword bit estimates satisfy a criterion symptomatic of the graph including a trapping set, at least a portion of the messages are reset before continuing the iterations. Alternatively, if the decoding fails to converge according to a predetermined failure criterion, at least a portion of the messages that are sent from the bit nodes are truncated before continuing the iterations.

### FIELD AND BACKGROUND OF THE INVENTION

Disclosed herein is a method and associated devices, for Low-Density Parity Check (LDPC) decoding, that overcomes non-convergence due to trapping sets.

Error Correction Codes (ECCs) are commonly used in communication systems and in storage systems. Various physical phenomena occurring both in communication channels and in storage devices result in noise effects that corrupt the communicated or stored information. Error correction coding schemes can be used for protecting the communicated or stored information against the resulting errors. This is done by encoding the information before transmission through the communication channel or storage in the memory device. The encoding process transforms the information bits sequence into a codeword by adding redundancy to the information. This redundancy can then be used in order to recover the information from the possibly corrupted codeword through a decoding process.

In both communication systems and storage systems an information bit sequence i is encoded into a coded bit sequence v that is modulated or mapped into a sequence of symbols x that is adapted to the communication channel or to the memory device. At the output of the communication channel or memory device a sequence of symbols y is obtained. An ECC decoder of the system decodes the sequence y and recovers the bit sequence î, which should reconstruct the original information bit sequence i with high probability.

A common ECC family is the family of linear binary block codes. A length N linear binary block code of dimension K is a linear mapping of length K information bit sequences into length N codewords, where N>K. The rate of the code is defined as R=K/N. The encoding process of a codeword v of dimension 1×N is usually done by multiplying the information bits sequence i of dimension 1×K by a generator matrix G of dimension K×N according to

v=i·G (1)

It is also customary to define a parity-check matrix H of dimension M×N, where M=N−K. The parity-check matrix is related to the generator matrix through the following equation:

GH^{T}=0 (2)

The parity-check matrix can be used in order to check whether a length N binary vector is a valid codeword. A 1×N binary vector v belongs to the code if and only if the following equation holds:

H·v′=0 (3)

(In equation (3), the prime on v′ means that v′ is a column vector.)

In recent years iterative coding schemes have become very popular. In these schemes the code is constructed as a concatenation of several simple constituent codes and is decoded using an iterative decoding algorithm by exchanging information between the constituent decoders of the simple codes. Usually, the code can be defined using a bipartite graph describing the interconnections between the constituent codes. In this case, decoding can be viewed as an iterative message passing over the graph edges.

A popular class of iterative codes is Low-Density Parity-Check (LDPC) codes. An LDPC code is a linear binary block code defined by a sparse parity-check matrix H. As shown in FIG. 1, the code can be defined equivalently by a sparse bipartite graph G=(V,C,E) with a set V of N bit nodes (N=13 in FIG. 1), a set C of M check nodes (M=10 in FIG. 1) and a set E of edges (E=38 in FIG. 1) connecting bit nodes to check nodes. The bit nodes correspond to the codeword bits and the check nodes correspond to parity-check constraints on the bits. A bit node is connected by edges to the check nodes that the bit node participates with. In the matrix representation of the code on the left side of FIG. 1 an edge connecting bit node i with check node j is depicted by a non-zero matrix element at the intersection of row j and column i.

Next to the first and last check nodes of FIG. 1 are shown the equivalent rows of equation (3). The symbol “⊕” means “XOR”.

LDPC codes can be decoded using iterative message passing decoding algorithms. These algorithms operate by exchanging messages between bit nodes and check nodes along the edges of the underlying bipartite graph that represents the code. The decoder is provided with initial estimates of the codeword bits (based on the communication channel output or based on the read memory content). These initial estimates are refined and improved by imposing the parity-check constraints that the bits should satisfy as a valid codeword (according to equation (3)). This is done by exchanging information between the bit nodes representing the codeword bits and the check nodes representing parity-check constraints on the codeword bits, using the messages that are passed along the graph edges.

In iterative decoding algorithms, it is common to utilize “soft” bit estimations, which convey both the bit estimations and the reliabilities of the bit estimations.

The bit estimations conveyed by the messages passed along the graph edges can be expressed in various forms. A common measure for expressing a “soft” bit estimation is as a Log-Likelihood Ratio (LLR)

$$log \frac{Pr ( v = 0 \vert current contraints and observations )}{Pr ( v = 1 \vert current constraints and observations )} ,$$

where the “current constraints and observations” are the various parity-check constraints taken into account in computing the message at hand and the observations y corresponding to the bits participating in these parity checks. Without loss of generality, for simplicity we assume hereinafter that LLR messages are used throughout. The sign of the LLR provides the bit estimation (i.e., positive LLR corresponds to v=0 and negative LLR corresponds to v=1). The magnitude of the LLR provides the reliability of the estimation (i.e., |LLR|=0 means that the estimation is completely unreliable and |LLR|=±∞ means that the estimation is completely reliable and the bit value is known).

Usually, the messages passed during the decoding along the graph edges between bit nodes and check nodes are extrinsic. An extrinsic message m passed from a node n on an edge e takes into account all the values received on edges connected to n other than edge e (this is why the message is called extrinsic: it is based only on new information).

One example of a message passing decoding algorithm is the Belief-Propagation (BP) algorithm, which is considered to be the best algorithm from among this family of message passing algorithms.

Let

$${P}_{v} = log \frac{Pr ( v = 0 \vert y )}{Pr ( v = 1 \vert y )}$$

denote the initial decoder estimation for bit v, based only on the received or read symbol y. Note that it is also possible that some of the bits are not transmitted through the communication channel or stored in the memory device, hence there is no y observation for these bits. In this case, there are two possibilities: 1) shortened bits—the bits are known a-priori and Pᵥ=±∞ (depending on whether the bit is 0 or 1). 2) punctured bits—the bits are unknown a-priori and

$${P}_{v} = log \frac{Pr ( v = 0 )}{Pr ( v = 1 )} ,$$

where Pr(v=0) and Pr(v=1) are the a-priori probabilities that the bit v is 0 or 1 respectively. Assuming the information bits have equal a-priori probabilities to be 0 or 1 and assuming the code is linear then

$${P}_{v} = log \frac{1 / 2}{1 / 2} = 0.$$

Let

$${Q}_{v} = log \frac{Pr ( v = 0 \vert \underline{y} , H \cdot \underline{v} = 0 )}{Pr ( v = 1 \vert \underline{y} , H \cdot \underline{v} = 0 )}$$

denote the final decoder estimation for bit v, based on the entire received or read sequence y and assuming that bit v is part of a codeword (i.e., assuming H·v=0).

Let Q_{vc} denote a message from bit node v to check node c. Let R_{cv} denote a message from check node c to bit node v.

The BP algorithm utilizes the following update rules for computing the messages:

The bit node to check node computation rule is:

$${Q}_{vc} = {P}_{v} + {\sum }_{{c}^{′} ∈ N ( v , G ) \backslash c} {R}_{{c}^{′} v} \qquad ( 4 )$$

Here, N(n, G) denotes the set of neighbors of a node n in the graph G and c′ ε N(v, G)\c refers to those neighbors excluding node ‘c’ (the summation is over all neighbors except c).

The check node to bit node computation rule is:

$${R}_{cv} = {ϕ}^{- 1} ( {\sum }_{{v}^{′} ∈ N ( c , G ) \backslash v} ϕ ( {Q}_{{v}^{′} c} ) ) \qquad ( 5 )$$

### Here,

$$ϕ ( x ) = \{ sign ( x ) , - log tanh ( \frac{\vert x \vert}{2} ) \}$$

and operations in the φ domain are done over the group {0,1}×R⁺ (this basically means that the summation here is defined as summation over the magnitudes and XOR over the signs). Analogous to the notation of equation (4), N(c, G) denotes the set of bit node neighbors of a check node c in the graph G and v′ ε N(c, G)\v refers to those neighbors excluding node ‘v’ (the summation is over all neighbors except v).

The final decoder estimation for bit v is:

$${Q}_{v} = {P}_{v} + {\sum }_{{c}^{′} ∈ N ( v , G )} {R}_{{c}^{′} v} \qquad ( 6 )$$

The order of passing messages during message passing decoding is called the decoding schedule. BP decoding does not imply utilizing a specific schedule—it only defines the computation rules (equations (4), (5) and (6)). The decoding schedule does not affect the expected error correction capability of the code. However, the decoding schedule can significantly influence the convergence rate of the decoder and the complexity of the decoder.

The standard message-passing schedule for decoding LDPC code is the flooding schedule, in which in each iteration all the variable nodes, and subsequently all the check nodes, pass new messages to their neighbors (R. G. Gallager, Low-Density Parity-Check Codes, Cambridge, Mass.: MIT Press 1963). The standard BP algorithm based on the flooding schedule is given in FIG. 2.

The standard implementation of the BP algorithm based on the flooding schedule is expensive in terms of memory requirements. We need to store a total of 2|V|+2|E| messages (for storing the Pᵥ, Qᵥ, Q_{vc} and R_{cv} messages). Moreover, the flooding schedule exhibits a low convergence rate and hence requires higher decoding logic (e.g., more processors on an ASIC) for providing a required error correction capability at a given decoding throughput.

More efficient, serial message passing decoding schedules, are known. In a serial message passing schedule, the bit or check nodes are serially traversed and for each node, the corresponding messages are sent into and out from the node. For example, a serial schedule can be implemented by serially traversing the check nodes in the graph in some order and for each check node c ε C the following messages are sent:

1.Q_{vc} for each v ε N(c) (i.e., all Q_{vc} messages into the node c)

2. R_{cv} for each v ε N(c) (i.e., all R_{cv} messages from node c)

Serial schedules, in contrast to the flooding schedule, enable immediate and faster propagation of information on the graph resulting in faster convergence (approximately two times faster). Moreover, serial schedule can be efficiently implemented with a significant reduction of memory requirements. This can be achieved by using the Qᵥ messages and the R_{cv} messages in order to compute the Q_{vc} messages on the fly, thus avoiding the need to use an additional memory for storing the Q_{vc} messages. This is done by expressing Q_{vc} as (Qᵥ-R_{cv}) based on equations (4) and (6). Furthermore, the same memory as is initialized with the a-priori messages Pᵥ is used for storing the iteratively updated Qᵥ a-posteriori messages. An additional reduction in memory requirements is obtained because in the serial schedule we only need to use the knowledge of N(c) ∀c ε C, while in the standard implementation of the flooding schedule we use both data structures N(c) ∀c ε C and N(v) ∀v ε V requiring twice as much memory for storing the code's graph structure. The serially scheduled decoding algorithm appears in FIG. 3.

To summarize, serial decoding schedules have the following advantages over the flooding schedule:
1) Serial decoding schedules speed up the convergence by a factor of 2 compared to the standard flooding schedule. This means that we need only half the decoder logic in order to provide a given error correction capability at a given throughput, compared to a decoder based on the flooding schedule.
2) Serial decoding schedules provide a memory-efficient implementation of the decoder. A RAM for storing only |V|+|E| messages is needed (instead of for storing 2|V|+2|E| messages as in the standard flooding schedule). Half the ROM size for storing the code's graph structure is needed compared to the standard flooding schedule.
3) “On-the-fly” convergence testing can be implemented as part of the computations done during an iteration, allowing convergence detection during an iteration and decoding termination at any point. This can save on decoding time and energy consumption.

### DEFINITIONS

The methods described herein are applicable to correcting errors in data in at least two different circumstances. One circumstance is that in which data are retrieved from a storage medium. The other circumstance is that in which data are received from a transmission medium. Both a storage medium and a transmission medium are special cases of a “channel” that adds errors to the data. The concepts of “retrieving” and “receiving” data are generalized herein to the concept of “importing” data. Both “retrieving” data and “receiving” data are special cases of “importing” data from a channel.

The data that are decoded by the methods presented herein are a representation of a codeword. The data are only a “representation” of the codeword, and not the codeword itself, because the codeword might have been corrupted by noise in the channel before one of the methods is applied for decoding.

### SUMMARY OF THE INVENTION

Iterative coding systems exhibit an undesired effect called error floor as shown in FIG. 4, where, below a certain “noise” level in the communication channel or in the memory device, the Block Error Rate (BER) at the output of the decoder starts to decrease much more slowly even though the “noise” that is responsible for the bit errors becomes smaller. This effect is problematic, especially in storage systems, where the required decoder output block error rate should be very small (˜10⁻¹⁰). Note that in FIG. 4 the noise increases to the right.

It is well known that the error correction capability and the error floor of an iterative coding system improve as the code length increases (this is true for any ECC system, but especially for iterative coding systems, in which the error correction capability is rather poor at short code lengths).

However, in conventional implementations of iterative coding systems, the memory complexity of the decoding hardware is proportional to the code length; hence using long codes incurs high complexity, even in the most efficient implementations known (e.g. serially scheduled decoders).

Therefore, presented herein are methods for implementing extremely long LDPC codes that provide very low error floor and near optimal error correction capability, using low complexity decoding hardware.

While properly designed LDPC codes are very powerful, and can correct a large number of errors in a code word, a phenomenon known as “trapping sets” may cause the decoder to fail, and increase the error floor of the code, even though the number of incorrect bits may be very small and may be confined to certain regions in the graph. Trapping sets are not well defined for general LDPC codes, but have been described as: “These are sets with a relatively small number of variable nodes such that the induced sub-graph has only a small number of odd degree check nodes.”

Trapping sets are related to the topology of the LDPC graph and to the specific decoding algorithm used, are hard to avoid and are hard to analyze.

Trapping sets are a problem in the field of storage since historically the reliability required from storage devices is relatively high, for example 1 bit error per 10¹⁴ stored bits. The result is that codes employed in memory device such as flash memory devices should exhibit low error floor, but trapping sets increase the error floor.

Therefore, one embodiment provided herein is a method of decoding a representation of a codeword that encodes K information bits as N>K codeword bits, the method including: (a) importing the representation of the codeword from a channel; (b) in a plurality of decoding iterations, updating estimates of the codeword bits by steps including, in a graph that includes N bit nodes and N−K check nodes, exchanging messages between the bit nodes and the check nodes; and (c) if (i) the decoding has failed to converge according to a predetermined failure criterion, and (ii) the estimates of the codeword bits satisfy a criterion symptomatic of the graph including a trapping set: re-setting at least a portion of the messages before continuing the iterations.

Another embodiment provided herein is a method of decoding a representation of a codeword that encodes K information bits as N>K codeword bits, the method including: (a) importing the representation of the codeword from a channel; (b) in a plurality of decoding iterations, updating estimates of the codeword bits by steps including, in a graph that includes N bit nodes and N−K check nodes, exchanging messages between the bit nodes and the check nodes; and (c) if according to a predetermined failure criterion, the decoding fails to converge, truncating at least a portion of the messages that are sent from the bit nodes before continuing the iterations.

Another embodiment provided herein is a decoder for decoding a representation of a codeword that encodes K information bits as N>K codeword bits, including a processor for decoding the representation of the codeword by executing an algorithm for updating estimates of the codeword by steps including: (a) in a plurality of decoding iterations, updating estimates of the codeword bits by steps including, in a graph that includes N bit nodes and N−K check nodes, exchanging messages between the bit nodes and the check nodes; and (b) if (i) the decoding has failed to converge according to a predetermined failure criterion, and (ii) the estimates of the codeword bits satisfy a criterion symptomatic of the graph including a trapping set: re-setting at least a portion of the messages before continuing the iterations.

Another embodiment provided herein is a decoder for decoding a representation of a codeword that encodes K information bits as N>K codeword bits, including a processor for decoding the representation of the codeword by executing an algorithm for updating estimates of the codeword by steps including: (a) in a plurality of decoding iterations, updating estimates of the codeword bits by steps including, in a graph that includes N bit nodes and N−K check nodes, exchanging messages between the bit nodes and the check nodes; and (b) if, according to a predetermined failure criterion, the decoding fails to converge, truncating at least a portion of the messages that are sent from the bit nodes before continuing the iterations.

Another embodiment provided herein is a memory controller including: (a) an encoder for encoding K information bits as a codeword of N>K codeword bits; and (b) a decoder including a processor for decoding the representation of the codeword by executing an algorithm for updating estimates of the codeword by steps including: (i) in a plurality of decoding iterations, updating estimates of the codeword bits by steps including, in a graph that includes N bit nodes and N−K check nodes, exchanging messages between the bit nodes and the check nodes, and (ii) if (A) the decoding has failed to converge according to a predetermined failure criterion, and (B) the estimates of the codeword bits satisfy a criterion symptomatic of the graph including a trapping set: re-setting at least a portion of the messages before continuing the iterations.

Another embodiment provided herein is a memory controller including: (a) an encoder for encoding K information bits as a codeword of N>K codeword bits; and (b) a decoder including a processor for decoding the representation of the codeword by executing an algorithm for updating estimates of the codeword by steps including: (i) in a plurality of decoding iterations, updating estimates of the codeword bits by steps including, in a graph that includes N bit nodes and N−K check nodes, exchanging messages between the bit nodes and the check nodes; and (ii) if, according to a predetermined failure criterion, the decoding fails to converge, truncating at least a portion of the messages that are sent from the bit nodes before continuing the iterations.

Another embodiment provided herein is a receiver including: (a) a demodulator for demodulating a message received from a communication channel, thereby producing a representation of a codeword that encodes K information bits as N>K codeword bits; and (b) a decoder including a processor for decoding the representation of the codeword by executing an algorithm for updating estimates of the codeword by steps including: (i) in a plurality of decoding iterations, updating estimates of the codeword bits by steps including, in a graph that includes N bit nodes and N−K check nodes, exchanging messages between the bit nodes and the check nodes, and (ii) if (A) the decoding has failed to converge according to a predetermined failure criterion, and (B) the estimates of the codeword bits satisfy a criterion symptomatic of the graph including a trapping set: re-setting at least a portion of the messages before continuing the iterations.

Another embodiment provided herein is a receiver including: (a) a demodulator for demodulating a message received from a communication channel, thereby producing a representation of a codeword that encodes K information bits as N>K codeword bits; and (b) a decoder including a processor for decoding the representation of the codeword by executing an algorithm for updating estimates of the codeword by steps including: (i) in a plurality of decoding iterations, updating estimates of the codeword bits by steps including, in a graph that includes N bit nodes and N−K check nodes, exchanging messages between the bit nodes and the check nodes; and (ii) if, according to a predetermined failure criterion, the decoding fails to converge, truncating at least a portion of the messages that are sent from the bit nodes before continuing the iterations.

Another embodiment provided herein is a communication system for transmitting and receiving a message, including: (a) a transmitter including: (i) an encoder for encoding K information bits of the message as a codeword of N>K codeword bits, and (ii) a modulator for transmitting the codeword via a communication channel as a modulated signal; and (b) a receiver including: (i) a demodulator for receiving the modulated signal from the communication channel and for demodulating the modulated signal, thereby providing a representation of the codeword, and (ii) a decoder including a processor for decoding the representation of the codeword by executing an algorithm for updating estimates of the codeword by steps including: (A) in a plurality of decoding iterations, updating estimates of the codeword bits by steps including, in a graph that includes N bit nodes and N−K check nodes, exchanging messages between the bit nodes and the check nodes, and (B) if (I) the decoding has failed to converge according to a predetermined failure criterion, and (II) the estimates of the codeword bits satisfy a criterion symptomatic of the graph including a trapping set: re-setting at least a portion of the messages before continuing the iterations.

Another embodiment provided herein is a communication system for transmitting and receiving a message, including: (a) a transmitter including: (i) an encoder for encoding K information bits of the message as a codeword of N>K codeword bits, and (ii) a modulator for transmitting the codeword via a communication channel as a modulated signal; and (b) a receiver including: (i) a demodulator for receiving the modulated signal from the communication channel and for demodulating the modulated signal, thereby providing a representation of the codeword, and (ii) a decoder including a processor for decoding the representation of the codeword by executing an algorithm for updating estimates of the codeword by steps including: (A) in a plurality of decoding iterations, updating estimates of the codeword bits by steps including, in a graph that includes N bit nodes and N−K check nodes, exchanging messages between the bit nodes and the check nodes; and (B) it according to a predetermined failure criterion, the decoding fails to converge, truncating at least a portion of the messages that are sent from the bit nodes before continuing the iterations.

Another embodiment provided herein is a method of decoding a representation of a codeword that encodes K information bits as N>K codeword bits, the method including: (a) importing the representation of the codeword from a channel; (b) providing a parity check matrix having N−K rows and N columns; (c) in a plurality of decoding iterations, updating estimates of the codeword bits by steps including exchanging messages between the rows and the columns of the matrix; and (d) if (i) the decoding has failed to converge according to a predetermined failure criterion, and (ii) the estimates of the codeword bits satisfy a criterion symptomatic of the parity check matrix including a trapping set: re-setting at least a portion of the messages before continuing the iterations.

Another embodiment provided herein is a method of decoding a representation of a codeword that encodes K information bits as N>K codeword bits, the method including: (a) importing the representation of the codeword from a channel; (b) providing a parity check matrix having N−K rows and N columns; (c) in a plurality of decoding iterations, updating estimates of the codeword bits by steps including exchanging messages between the rows and the columns; and (d) if according to a predetermined failure criterion, the decoding fails to converge, truncating at least a portion of the messages that are sent from the columns before continuing the iterations.

Another embodiment provided herein is a decoder for decoding a representation of a codeword that encodes K information bits as N>K codeword bits, including a processor for decoding the representation of the codeword by executing an algorithm for updating estimates of the codeword by steps including: (a) providing a parity check matrix having N−K rows and N columns; (b) in a plurality of decoding iterations, updating estimates of the codeword bits by steps including exchanging messages between the rows and the columns; and (c) if (i) the decoding has failed to converge according to a predetermined failure criterion, and (ii) the estimates of the codeword bits satisfy a criterion symptomatic of the parity check matrix including a trapping set: re-setting at least a portion of the messages before continuing the iterations.

Another embodiment provided herein is a decoder for decoding a representation of a codeword that encodes K information bits as N>K codeword bits, including a processor for decoding the representation of the codeword by executing an algorithm for updating estimates of the codeword by steps including: (a) providing a parity check matrix having N−K rows and N columns; (b) in a plurality of decoding iterations, updating estimates of the codeword bits by steps including exchanging messages between the rows and the columns; and (c) if, according to a predetermined failure criterion, the decoding fails to converge, truncating at least a portion of the messages that are sent from the columns before continuing the iterations.

Another embodiment provided herein is a memory controller including: (a) an encoder for encoding K information bits as a codeword of N>K codeword bits; and (b) a decoder including a processor for decoding the representation of the codeword by executing an algorithm for updating estimates of the codeword by steps including: (i) providing a parity check matrix having N−K rows and N columns; (ii) in a plurality of decoding iterations, updating estimates of the codeword bits by steps including exchanging messages between the rows and the columns, and (iii) if (A) the decoding has failed to converge according to a predetermined failure criterion, and (B) the estimates of the codeword bits satisfy a criterion symptomatic of the parity check matrix including a trapping set: re-setting at least a portion of the messages before continuing the iterations.

Another embodiment provided herein is a memory controller including. (a) an encoder for encoding K information bits as a codeword of N>K codeword bits; and (b) a decoder including a processor for decoding the representation of the codeword by executing an algorithm for updating estimates of the codeword by steps including: (i) providing a parity check matrix having N−K rows and N columns; (ii) in a plurality of decoding iterations, updating estimates of the codeword bits by steps including exchanging messages between the rows and the columns; and (iii) if according to a predetermined failure criterion, the decoding fails to converge, truncating at least a portion of the messages that are sent from the columns before continuing the iterations.

Another embodiment provided herein is a receiver including: (a) a demodulator for demodulating a message received from a communication channel, thereby producing a representation of a codeword that encodes K information bits as N>K codeword bits; and (b) a decoder including a processor for decoding the representation of the codeword by executing an algorithm for updating estimates of the codeword by steps including. (i) providing a parity check matrix having N−K rows and N columns; (ii) in a plurality of decoding iterations, updating estimates of the codeword bits by steps including exchanging messages between the rows and the columns, and (iii) if (A) the decoding has failed to converge according to a predetermined failure criterion, and (B) the estimates of the codeword bits satisfy a criterion symptomatic of the parity check matrix including a trapping set: re-setting at least a portion of the messages before continuing the iterations.

Another embodiment provided herein is a receiver including: (a) a demodulator for demodulating a message received from a communication channel, thereby producing a representation of a codeword that encodes K information bits as N>K codeword bits; and (b) a decoder including a processor for decoding the representation of the codeword by executing an algorithm for updating estimates of the codeword by steps including: (i) providing a parity check matrix having N−K rows and X columns; (ii) in a plurality of decoding iterations, updating estimates of the codeword bits by steps including exchanging messages between the rows and the columns; and (iii) if, according to a predetermined failure criterion, the decoding fails to converge, truncating at least a portion of the messages that are sent from the columns before continuing the iterations.

Another embodiment provided herein is a communication system for transmitting and receiving a message, including: (a) a transmitter including: (i) an encoder for encoding K information bits of the message as a codeword of N>K codeword bits, and (ii) a modulator for transmitting the codeword via a communication channel as a modulated signal; and (b) a receiver including; (i) a demodulator for receiving the modulated signal from the communication channel and for demodulating the modulated signal, thereby providing a representation of the codeword, and (ii) a decoder including a processor for decoding the representation of the codeword by executing an algorithm for updating estimates of the codeword by steps including: (A) providing a parity check matrix having N−K rows and N columns; (B) in a plurality of decoding iterations, updating estimates of the codeword bits by steps including exchanging messages between the rows and the columns, and (C) if (I) the decoding has failed to converge according to a predetermined failure criterion, and (II) the estimates of the codeword bits satisfy a criterion symptomatic of the parity check matrix including a trapping set: re-setting at least a portion of the messages before continuing the iterations.

Another embodiment provided herein is a communication system for transmitting and receiving a message, including; (a) a transmitter including: (i) an encoder for encoding K information bits of the message as a codeword of N>K codeword bits, and (ii) a modulator for transmitting the codeword via a communication channel as a modulated signal; and (b) a receiver including: (i) a demodulator for receiving the modulated signal from the communication channel and for demodulating the modulated signal, thereby providing a representation of the codeword, and (ii) a decoder including a processor for decoding the representation of the codeword by executing an algorithm for updating estimates of the codeword by steps including: (A) providing a parity check matrix having N−K rows and N columns; (B) in a plurality of decoding iterations, updating estimates of the codeword bits by steps including exchanging messages between the rows and the columns; and (C) if, according to a predetermined failure criterion, the decoding fails to converge, truncating at least a portion of the messages that are sent from the columns before continuing the iterations.

Four general methods are provided herein for decoding a representation, that has been imported from a channel, of a codeword that encodes K information bits as N>K codeword bits.

According to the first two general methods, in a plurality of decoding iterations, estimates of the codeword bits are updated by exchanging messages between the bit nodes and the check nodes of a graph that includes N bit nodes and N−K check nodes.

According to the first general method, if the decoding has failed according to a predetermined failure criterion, and if the codeword bit estimates satisfy a criterion symptomatic of the graph including a trapping set, at least a portion of the messages are re-set before continuing the iterations.

In some embodiments of the first general method, at least a portion of the graph is partitioned into a plurality of subgraphs. At least a portion of the exchanging of the messages is effected separately within each subgraph. The associated criterion of the graph including a trapping set includes failure of the decoding to converge in only one of the subgraphs.

Another criterion of the graph including a trapping set is that at most about one percent of the elements of a syndrome of the codeword bit estimates are non-zero and constant in two consecutive iterations.

The re-setting of the at least portion of the messages preferably includes setting at least a portion of the messages to be sent from the check nodes, and/or truncating at least a portion of the messages to be sent from the bit nodes. Most preferably, the re-setting includes setting all the messages to be sent from the check nodes to zero, and/or truncating all the messages to be sent from the bit nodes. Preferably, the messages that are to be sent from the bit nodes are log likelihood ratios, of which the messages that are truncated are truncated to a magnitude of at most between about 10 and about 16.

According to the second general method, if, according to a predetermined failure criterion, the decoding fails to converge, at least a portion of the messages that are sent from the bit nodes are truncated before continuing the iterations.

One preferred failure criterion includes at least a predetermined number of elements (e.g. one element) of a syndrome of the codeword bit estimates being non-zero, for example after a pre-determined number of iterations, or after a pre-determined time, or after a pre-determined number of exchanges of messages between the bit nodes and the check nodes. Another preferred failure criterion includes at most a predetermined number of elements of a syndrome of the codeword bit estimates remaining non-zero in two consecutive iterations. Another preferred failure criterion includes the difference between the numbers of non-zero elements of a syndrome of the codeword bit estimates after two consecutive iterations being less than a predetermined limit. Another preferred failure criterion includes the Hamming distance between the codeword bit estimates before and after a predetermined number of consecutive iterations (e.g. before and after a single iteration) being less than a predetermined limit.

Preferably, all the messages that are sent from the bit nodes are truncated.

Preferably, the messages are log likelihood ratios and the messages that are truncated are truncated to a magnitude of at most between about 10 and about 16.

As noted above, the graphical representation of LDPC decoding is equivalent to a matrix representation, as illustrated in FIG. 1. Therefore, according to the third and fourth general methods, estimates of the codeword bits are updated using a parity check matrix to connect a bit vector having N bit vector elements and a check vector having N−K check vector elements. In a plurality of decoding iterations, estimates of the codeword bits are updated by exchanging messages between the bit vector elements and the check vector elements that are so connected.

According to the third general method, if the decoding has failed according to a predetermined failure criterion, and if the codeword bit estimates satisfy a criterion symptomatic of the parity check matrix including a trapping set, at least a portion of the messages are re-set before continuing the iterations.

According to the fourth general method, if, according to a predetermined failure criterion, the decoding fails to converge, at least a portion of the messages that are sent from the columns are truncated before continuing the iterations.

A decoder corresponding to one of the four general methods includes one or more processors for decoding the representation of the codeword by executing an algorithm for updating the codeword bit estimates according to the corresponding general method.

A memory controller corresponding to one of the four general methods includes an encoder for encoding K information bits as a codeword of N>K bits and a decoder that corresponds to the general method. Normally, such a memory controller includes circuitry for storing at least a portion of the codeword in a main memory and for retrieving a (possibly noisy) representation of the at least portion of the codeword from the main memory. A memory device corresponding to one of the four general methods includes such a memory controller and also includes the main memory.

A receiver corresponding to one of the four general methods includes a demodulator for demodulating a message received from a communication channel. The demodulator provides a representation of a codeword that encodes K information bits as N>K codeword bits. Such a receiver also includes a decoder that corresponds to the general method.

A communication system corresponding to one of the four general methods includes a transmitter and a receiver. The transmitter includes an encoder for encoding K information bits of a message as a codeword of N>K codeword bits and a modulator for transmitting the codeword via a communication channel as a modulated signal. The receiver is a receiver that corresponds to the general method.

### BRIEF DESCRIPTION OF THE DRAWINGS

Various embodiments are herein described, by way of example only, with reference to the accompanying drawings, wherein:

FIG. 1 shows how a LDPC code can be represented as either a sparse parity check matrix or a sparse bipartite graph;

FIG. 2 shows a flooding schedule belief propagation algorithm;

FIG. 3 shows a conventional serial schedule belief propagation algorithm;

FIG. 4 illustrates error floor;

FIG. 5 shows how messages are exchanged within a sub-graph and between a sub-graph and a set of external check nodes;

FIG. 6 shows a belief propagation algorithm in which messages are exchanged within sub-graphs and between the sub-graphs and a set of external check nodes;

FIGS. 7A and 7B are high-level schematic block diagrams of decoders for implementing the algorithm of FIG. 6;

FIGS. 8 and 9 show two ways of partitioning the sparse bipartite graph of FIG. 1 into sub-graphs;

FIG. 10 is a high-level schematic block diagram of a flash memory device whose controller includes the decoder of FIG. 7A;

FIG. 11 is a detail of FIG. 10;

FIG. 12 is a high-level schematic block diagram of a communication system whose receiver includes the decoder of FIG. 7A.

### DESCRIPTION OF THE PREFERRED EMBODIMENTS

The principles and operation of low-complexity LPDC decoding and of LPDC decoding that overcomes non-convergence due to trapping sets may be better understood with reference to the drawings and the accompanying description.

In conventional decoders for LDPC codes, the memory required by the decoder is proportional to the code length N (equal to the number of variable nodes in the code's underlying graph |V|) and to the number of edges in the code's underlying graph |E|. In efficient implementations (e.g. based on serially scheduled decoders), the required memory can be as small as (|V|+|E|)*bpm bits, where |V| is the number of bit estimations, |E| is the number of edge messages and bpm is the number of bits per message stored in the memory of the decoder (note that we assume here that the same number of bits is required for storing bit estimation and edge message, for the sake of simplicity, though this is not necessarily the case). The decoder presented herein uses much smaller memory for implementing the decoding, storing only a small fraction of the |V| bit estimations and of the |E| edge messages simultaneously, without any degradation in decoder's error correction capability, compared to a conventional decoder, assuming sufficient decoding time is available. This is achieved by employing an appropriate decoding schedule and using the decoding hardware described herein.

The methods and decoders described herein operate by dividing the underlying graph representing the code into several sections and to implement the message passing decoding algorithm by sequentially processing the different sections of the graph, one or more sections at a time. At each stage during decoding only the bit estimations and edge messages corresponding to the graph section(s) that is/are currently being processed are stored. This way a very long LDPC code can be employed, providing near optimal error correction capability and very low error floor, while utilizing a low complexity decoding hardware.

The decoders presented herein are highly suitable for usage in memory devices, principally for the three following reasons:
1. A low FCC error floor is especially important in memory devices, which have severe decoder output BER requirements (<10⁻¹⁵). When short codes are used, achieving such low error floor is very hard and usually requires sacrificing the error correction capability of the code, which is already compromised due to the short length of the code. Therefore using an equivalent long code the error correction capability of the code is improved, and thus lower FCC redundancy is required for protecting information against a given memory “noise” which corrupts the stored data. This in turn results in better cost efficiency of the memory, because a larger amount of information can be stored in a given number of memory cells (or using a given memory silicon size). Hence, employing a long ECC in memory devices is expected to provide a significant advantage.
2. The LDPC methods presented herein allow for processing a section of the coders underlying graph at each processing phase, instead of the entire graph at once. This means that we can store only a part of the “soft” bit estimations at each phase and not all of the “soft” bit estimations at once. Here the term “soft” bit estimates refers to a collection of bits describing the reliability of an estimate ‘y’ for each stored bit deduced from reading from the storage (possibly flash device).

This feature can be easily utilized in a memory device, because only the presently required bit observations (y) can be read from the storage device, hence there is no need for a large buffer in the memory controller in order to implement the ECC decoding. Alternatively, even if all bit observations (represented by the vector y) are read from the memory at once, the buffer required for storing them is usually much smaller than the memory required for storing the bit observations (the Pᵥ messages) required by the decoder. This way, only part of the soft bit estimates corresponding to the graph section that is currently being processed by the decoder are generated each time, resulting in a smaller decoder memory requirement.

Consider for example a SLC Flash memory device (a Flash memory device that stores one bit per cell; “SLC” means “Single Level Cell” and actually is a misnomer because each cell supports two levels; the “S” in “SLC” refers to there being only one programmed level), in which each cell stores a single bit v and the state y read from each cell can be either 0 or 1. Then the memory needed for storing the vector y of read cell states is N bits. On the other hand, the memory required for storing all the soft bit estimates (Pᵥ messages) can be larger (for example 6N bits if each LLR estimate is stored in 6 bits). Hence, it is more efficient to generate only the required soft bit estimates in each decoder activation. A LLR bit estimate

$${P}_{v} = log \frac{Pr ( v = 0 \vert y )}{Pr ( v = 1 \vert y )}$$

for some bit v can be generated from the corresponding bit observations y that are read from the flash memory device based on an a-priori knowledge of the memory “noise”. In other words, by knowing the memory “noise” statistics we can deduce the probability that a bit v that was stored in a certain memory cell is 0/1 given that ‘y’ is read from the cell.

For example, assume that in a certain SLC Flash memory device the probability of reading the state of the cell different than the one it was programmed to is p=10⁻², then if y=0 then

$${P}_{v} = log \frac{1 - p}{p} = 4.6$$

and if y=1 then

$${P}_{v} = log \frac{p}{1 - p} = - 4.6 .$$

Furthermore, if the number of states that can be read from each cell of the flash device (represented by ‘y’) is 8 because the cell stores a single bit (one “hard bit”) and the device is configured to read eight threshold voltage levels, equivalent to two ‘soft bits”, then each element ‘y’ which requires, in the controller, storage for 3 bits, is convened to an LLR value Pᵥ that may be represented as more than 3 bits, for example as 6 bits (BPM=Bits Per Message=6). These 6 bits are a soft bit estimate as opposed to the 2 soft bits read from the flash cell and corresponding to this 6-bit LLR value.
3. A decoding schedule of the type presented herein allow for a smaller memory requirement (compared with conventional decoding schedules). However, the decoding schedules presented herein might slow down the decoder convergence rate and increase the decoding time, especially when operating near the decoder's maximal error correction capability. Such a decoder is highly suitable for memory devices, which can tolerate variable ECC decoding latencies. For example, if the required decoding time for the ECC to converge to the correct stored codeword is long due to a high number of corrupted bits, then the memory controller can stop reading the memory until the decoding of the previously read codeword is finalized. Note that during most of a flash memory device's life, the memory “noise” is small and the number of corrupted bits is small. Hence, the decoder operates efficiently and quickly, allowing for an efficient pipelined memory reading. Rarely, the number of corrupted bits read from the memory is high, requiring longer decoding time and resulting in a reading pipeline stall. Therefore on average the throughput is left unharmed even with these variable decoding time characteristics.

According to one class of embodiments, the bipartite graph G=(V,C,E) that represents the code is divided into several sections in the following way. 1) Divide the set V of bit nodes into t disjoint subsets: V₁, V₂, . . . , Vₜ (such that V=V₁∪V₂∪ . . . ∪Vₜ). 2) For each subset Vᵢ of bit nodes, form a subset Cᵢ of check nodes, including all of the check nodes that are connected solely to the bit nodes in Vᵢ. 3) Form a subset C_{J} of external check nodes, including all of the check nodes that are not in any of the check node subsets formed so far, i.e. C_{J}=C\(C₁∪C₂∪ . . . ∪Cₜ). 4) Divide the graph G into t sub-graphs G₁, G₂, . . . , Gₜ such that Gᵢ=(Vᵢ,Cᵢ,Eᵢ) where Eᵢ is the set of edges connected between bit nodes in Vᵢ and check nodes in Cᵢ. Denote the edges connected to the set C_{J} by E_{J}(note that E_{J}=E\(E₁∪E₂∪ . . . ∪Eₜ)).

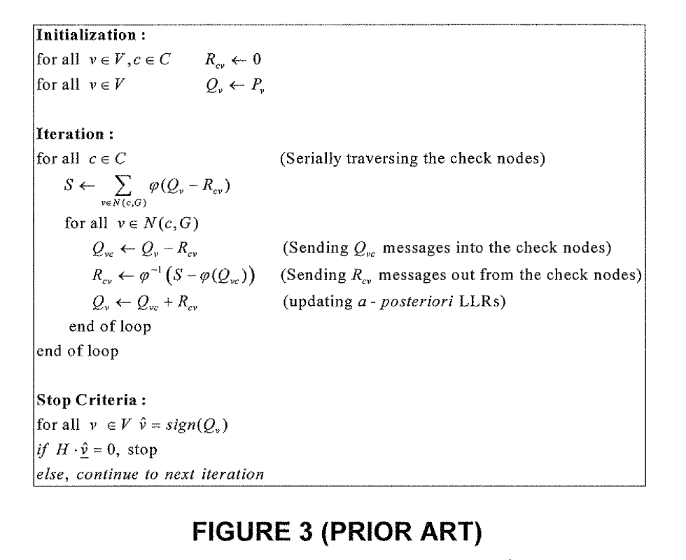

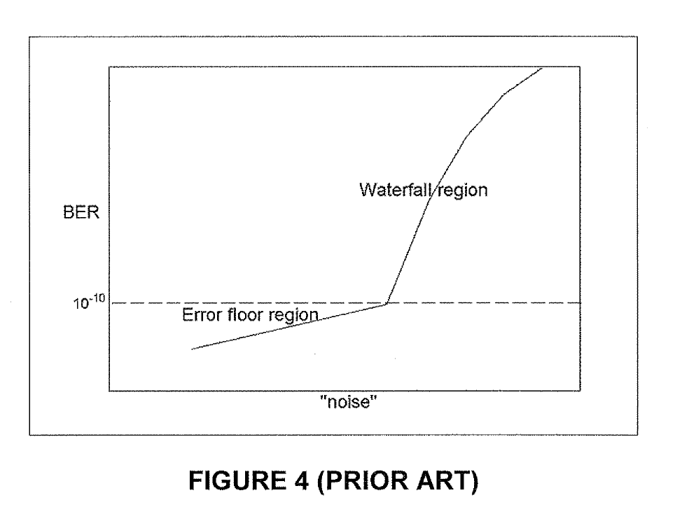

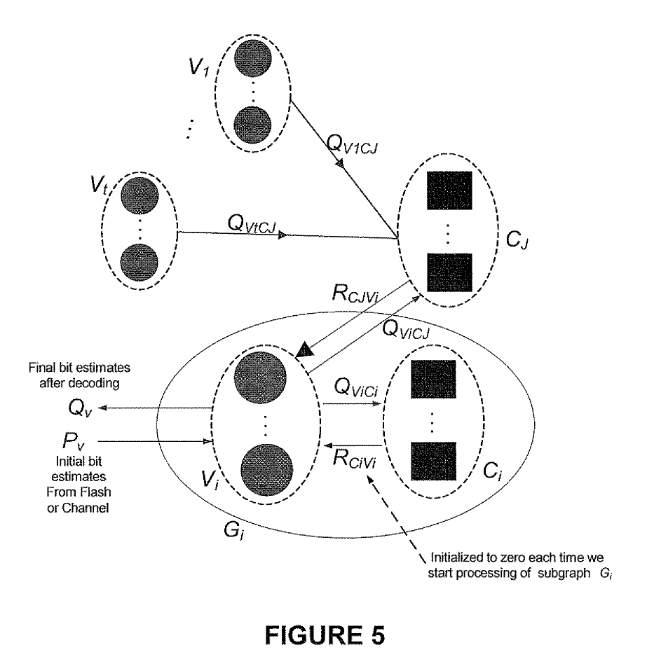

In these embodiments, the graph G is processed according to a special message passing schedule, by iteratively performing decoding phases, and in each decoding phase exchanging messages along the graph edges in the following order:
for i=1 through t
   1. Send R_{cv} messages from check nodes c ε C_{J} to bit nodes v ε Vᵢ along edges in E_{J}, depicted as the R_{CJVi} messages in FIG. 5. Set R_{cv} messages from check nodes c ε Cᵢ to bits nodes v ε Vᵢ to zero, depicted by the Rcᵢvᵢ messages in FIG. 5. Set initial bit estimations to Pᵥ for every bit v ε Vᵢ, depicted as the P_{Vi} messages in FIG. 5. Note that the messages R_{CJVi} are the result of activating the decoder for the other t-1 sub-graphs Gₖ, k≠i, prior to this step. In the event that other sub-graphs have not been processed yet, their corresponding messages Q_{vicJ} in FIG. 5 are set to Pᵥᵢ, i.e., the estimates read from the memory or received from the communication channel In case those are punctured bits, their Pᵥᵢ's are zero.
   2. Perform one or more iterations by sending Q_{vc} messages from bit nodes in Vᵢ to check nodes in Cᵢ, and R_{cv} messages from check nodes in Cᵢ to bit nodes in Vᵢ, along the edges in Eᵢ, according to some schedule (e.g. according to the serial schedule described in FIG. 3, performed by serially traversing the check nodes in Cᵢ and for each check node sending the messages to and from that check node). This is depicted as the Qvᵢcᵢ and Rcᵢvᵢ messages in FIG. 5.
   3. Send Q_{vc} messages from bit nodes in Vᵢ to check nodes in C_{J} along the edges in E_{J}, depicted as the Qvᵢc_{J} messages in FIG. 5.

Decoding continues until the decoder converges to a valid codeword, satisfying all the parity-check constraints, or until a maximum number of allowed decoding phases is reached. The stopping criterion for the message passing within each sub-graph i is similar: iterate until either all the parity-check constraints within this sub-graph are satisfied or a maximum number of allowed iterations is reached. In general, the maximum allowed number of iterations may change from one sub-graph to another or from one activation of the decoder to another.

The messages sent along the edges in E_{J} (R_{CJVi} messages and Qvᵢc_{J} messages in FIG. 5) are used for exchanging information between the different sections of the graph. The messages that are sent at each stage during decoding can be computed according to the standard computation rules of the message passing decoding algorithm. For example, if BP decoding is implemented then the messages are computed according to equations (4) and (5). Other message-passing decoding algorithms, such as Min Sum algorithms, Gallagher A algorithms and Gallagher B algorithms, have their own computation rules.

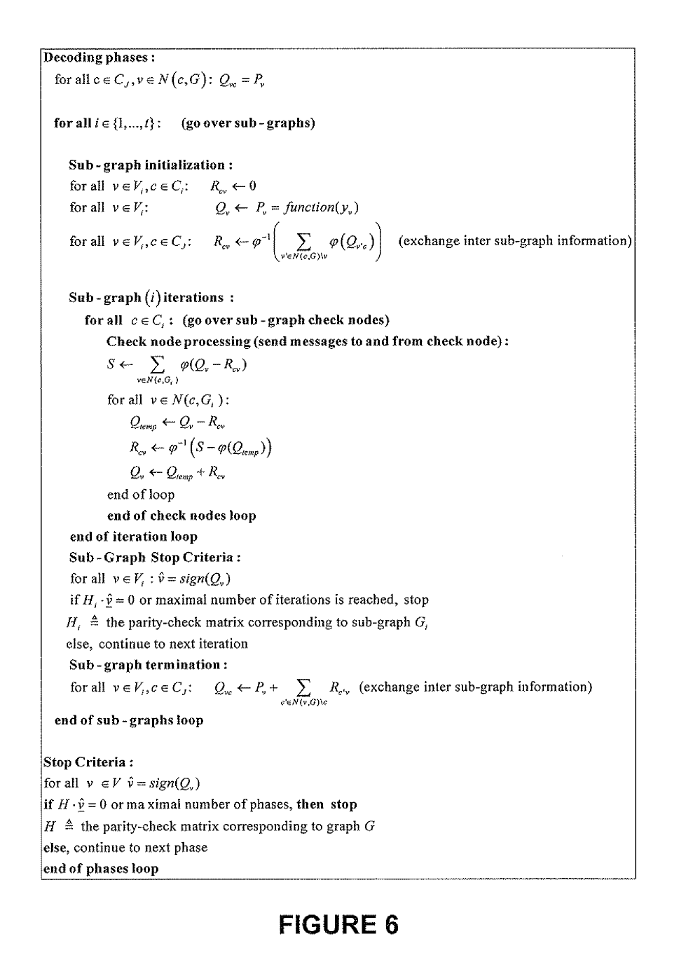

Such a decoding algorithm, assuming serially scheduled message passing decoding within each sub-graph, implementing BP decoding, is summarized in FIG. 6. In this algorithm, at each stage during decoding only the Qᵥ messages corresponding to bit nodes v ε Vᵢ, the R_{cv} messages corresponding to the edges in Eᵢ and the messages corresponding to the edges in E_{J} are stored. Hence, the decoder of this class of embodiments requires storing only (max{|V₁|,|V₂|, . . . ,|Vₜ|}+max{|E₁|,|E₂|, . . . ,|Eₜ|}+|E_{J}|) messages simultaneously, compared to (|V|+|E|) messages in efficient conventional decoders. Thus the memory requirement is ˜1/t fraction of the memory required for a conventional decoder. When implementing long LDPC codes this provides a significant advantage in a decoder's complexity.

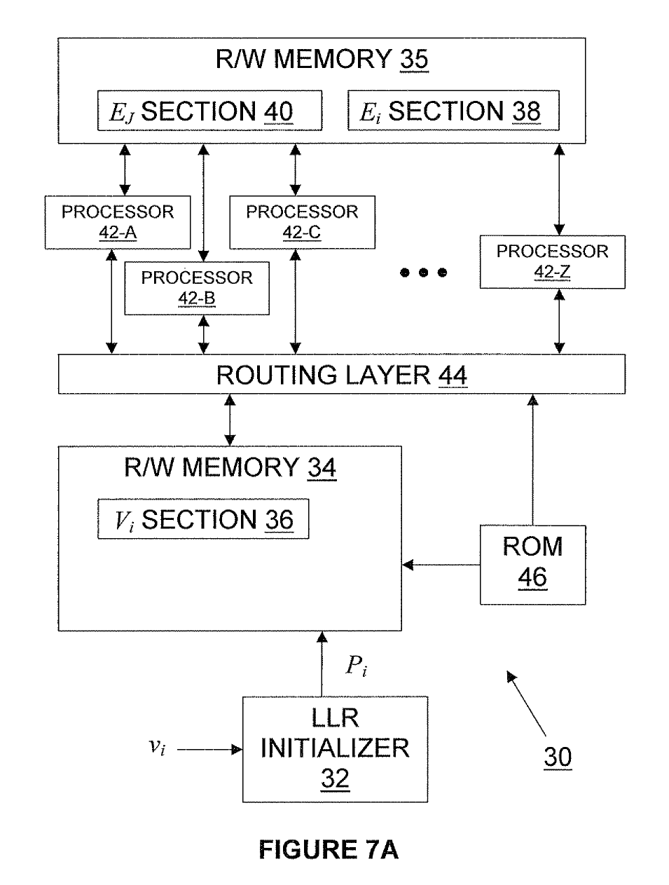

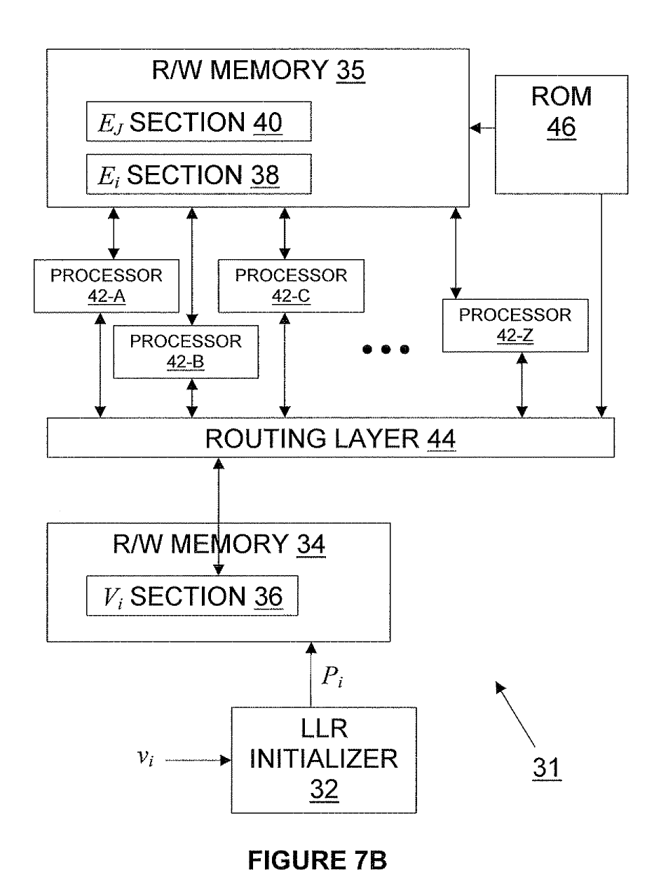

A high-level schematic block diagram of an exemplary decoder 30 according to this class of embodiments is shown in FIG. 7A. Decoder 30 includes:
1. An initial LLRs computation block 32 that computes the initial bit estimations Pₜ=[Pᵥ: v ε Vᵢ] for bits v ε Vᵢ in the currently processed sub-graph Gᵢ=(Vᵢ, Cᵢ, Eᵢ), based on the corresponding bit observations yₜ=[yᵥ: v ε Vᵢ] read from the memory or received from the communication channel (where yᵥ is the observation corresponding to bit v).
2. A read/write memory 34 including a memory section 36 for storing the bit estimations for bit nodes v ε Vᵢ in the currently processed sub-graph (Qᵥ messages which are initialized as the Pᵥ messages).
3. A read/write memory 35 including:
   3a. A memory section 38 for storing the R_{cv} messages corresponding to the edge set Eᵢ of the currently processed sub-graph.
   3b. A memory section 40 for storing the messages along the edges in E_{J}. Memory section 40 stores: i) the Q_{vc} messages from bit nodes v ε Vᵢ, ∀i′ε {1, . . . , n}\i to check nodes c ε C_{J}, where i is the index of the currently processed sub-graph; and ii) for bit nodes v ε Vᵢ memory section 40 first stores the R_{cv} messages from check nodes c ε C_{J} and afterwards the sub-graph's processing memory section 40 stores the Q_{vc} to check nodes c ε C_{J}.
4. Processing units 42 for implementing the computations involved in updating the messages (as shown in FIG. 6).
5. A routing layer 44 that routes messages between memory 34 and processing units 42. For example, in some sub-classes of this class of embodiments, within the loop over sub-graphs G₁ through Gₜ in FIG. 6, routing layer 44 assigns each processor 42 its own check node of the current sub-graph Gᵢ and the check node processing is done in parallel for all the check nodes of Gᵢ (or for as many check nodes of Gᵢ as there are processors 42).
6. A read-only memory (ROM) 46 for storing the code's graph structure. Memory addressing, and switching by routing layer 44, are based on entries in ROM 46.

Decoder 30 includes a plurality of processing units 42 so that the computations involved in updating the messages may be effected in parallel. An alternative embodiment with only one processing unit 42 would not include a routing layer 44.

As noted above, a serial passing schedule traverses serially either the check nodes or the bit nodes. Decoder 30 of FIG. 7A traverses the check nodes serially. FIG. 7B is a high-level schematic block diagram of a similar decoder 31 that traverses the bit nodes serially.

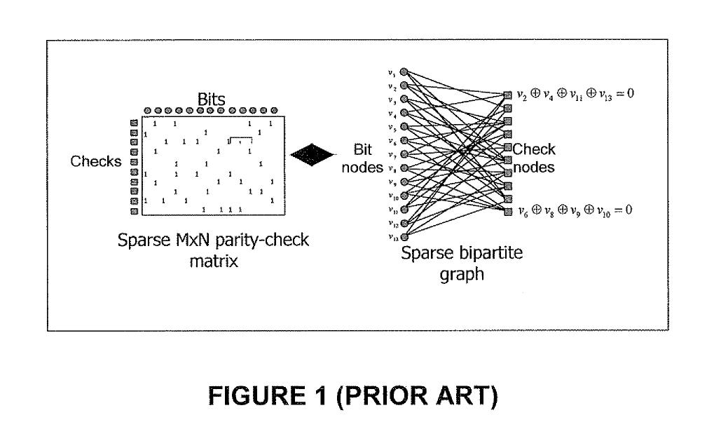

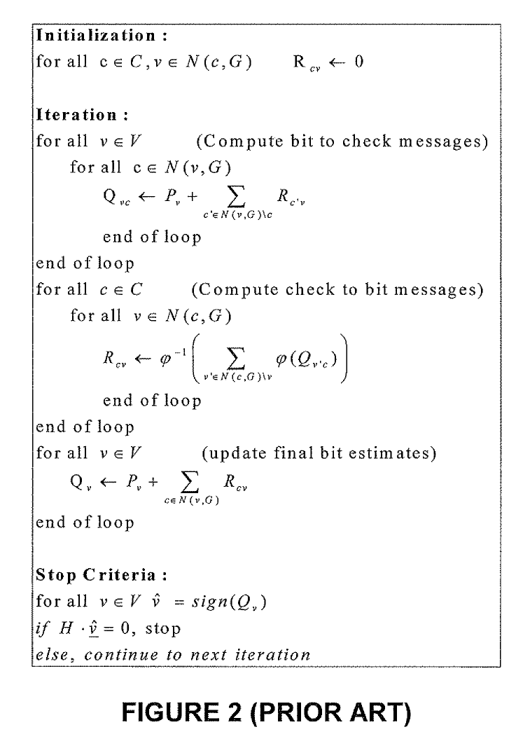

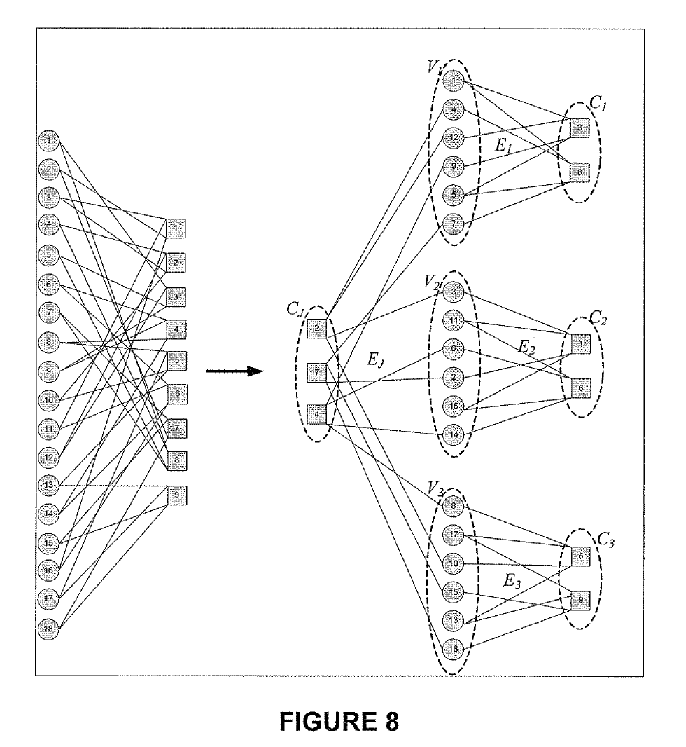

An example of the graph partitioning according to this class of embodiments is shown in FIG. 8. An LDPC code which is described by a regular bipartite graph with 18 bit nodes and 9 check nodes, such that every bit node is connected to two check nodes and every check node is connected to four bit nodes, is used in this example. This is a length 18, rate ½ LDPC code. The original graph is shown on the left side of FIG. 8. This also is the graph of FIG. 1. The graph after partitioning its bit nodes, check nodes and edges into subsets is shown on the right side of FIG. 8. Note that this is the same graph, only rearranged for sake of clarity. For this code, a prior art efficient decoder would require storing 18+36=54 messages, while the corresponding decoder 30 requires storing only 6+8+12=26 messages, providing 52% reduction in the decoder's memory complexity, while maintaining the same error correction capability.

It is preferred that all the sub-graphs be topologically identical, as in the example of FIG. 8. In this context, “topological identity” means that all the sub-graphs have equal numbers of bit nodes and equal numbers of check nodes; that each bit node has a corresponding bit node in every other sub-graph in terms of connectivity to internal check nodes; and that each sub-graph check node has a 20 corresponding check node in every other sub-graph in terms of connectivity to bit nodes. For example, in FIG. 8;
Bit nodes 1, 5, 11, 13, 16 and 17 correspond because bit nodes 1 and 5 are connected to both check nodes of sub-graph 1, bit nodes 11 and 16 are connected to both check nodes of sub-graph 2, bit nodes 13 and 17 are connected to both check nodes of sub-graph 3, and none of these bit nodes is connected to an external check node (a check node of set C_{J}).
The remaining bit nodes correspond because each of these bit nodes is connected to one check node of the same sub-graph.
All the check nodes of the sub-graphs correspond because each one of these check nodes is connected to the two bit nodes of its sub-graph that are connected only to sub-graph check nodes and to two other bits of its sub-graph that are also connected to external check nodes.
   Note that the sub-graphs need not have identical connectivity to the external check nodes in order to be “topologically identical”. For example, the two bit nodes, 15 and 18, of sub-graph 3, that are connected to the same external check node 7, are also connected to the same check node 9 of sub-graph 3, but the two bit nodes, 4 and 12, of sub-graph 1, that are connected to the same external check node 2, are connected to different check nodes (3 and 8) of sub-graph 1.

If need be, however, any LDPC graph G can be partitioned into sub-graphs by a greedy algorithm. The first sub-graph is constructed by selecting an arbitrary set of bit nodes. The check nodes of the first sub-graph are the check nodes that connect only to those bit nodes. The second sub-graph is constructed by selecting an arbitrary set of bit nodes from among the remaining bit nodes. Preferably, of course, the number of bit nodes in the second sub-graph is the same as the number of bit nodes in the first sub-graph. Again, the check nodes of the second sub-graph are the check nodes that connect only to the bit nods of the second sub-graph. This is arbitrary selection of bit nodes is repeated as many times as desired. The last sub-graph then consists of the bit nodes that were not selected and the check nodes that connect only to those bit nodes. The remaining check nodes constitute C_{J}.

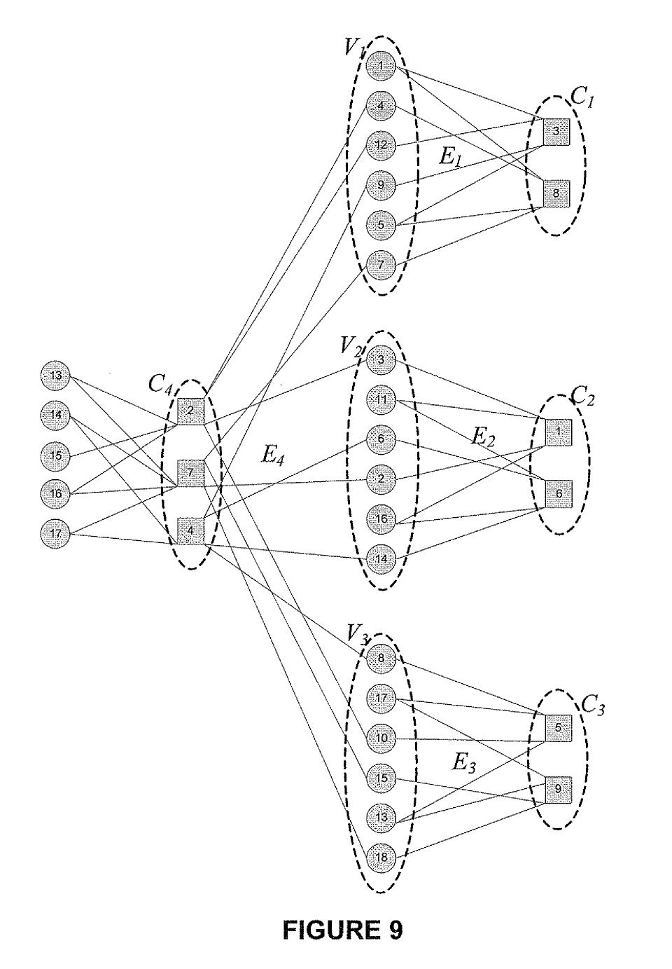

In the class of embodiments described above, the LDPC graph G is partitioned into t sub-graphs, each with its own bit nodes and check nodes, plus a separate subset C_{J} of only check nodes. In another class of embodiments, as illustrated in FIG. 9, G is partitioned into just t sub-graphs, each with its own bit nodes and check nodes. For example, using the greedy algorithm described above, the last sub-graph (Gₜ) includes the non-selected bit nodes, the check nodes that connect only to these bit nodes, and also all the remaining check nodes. This is equivalent to the set C_{J} of the first class of embodiments being connected to its own subset of bit nodes separate from the bit nodes of the sub-graphs. In this class of embodiments, the algorithm of FIG. 6 is modified by including only sub-graphs Gₜ through Gₜ₋₁ in the sub-graphs loop and ending each decoding phase by following the sub-graphs loop with a separate exchange of messages exclusively within Gₜ. FIG. 9 shows the case of t=4. In one sub-class of these embodiments, some of the bits are punctured bits, and Gₜ is dedicated to these bits: all the bits of Gₜ are punctured bits, and all the punctured bits are bits of Gₜ.

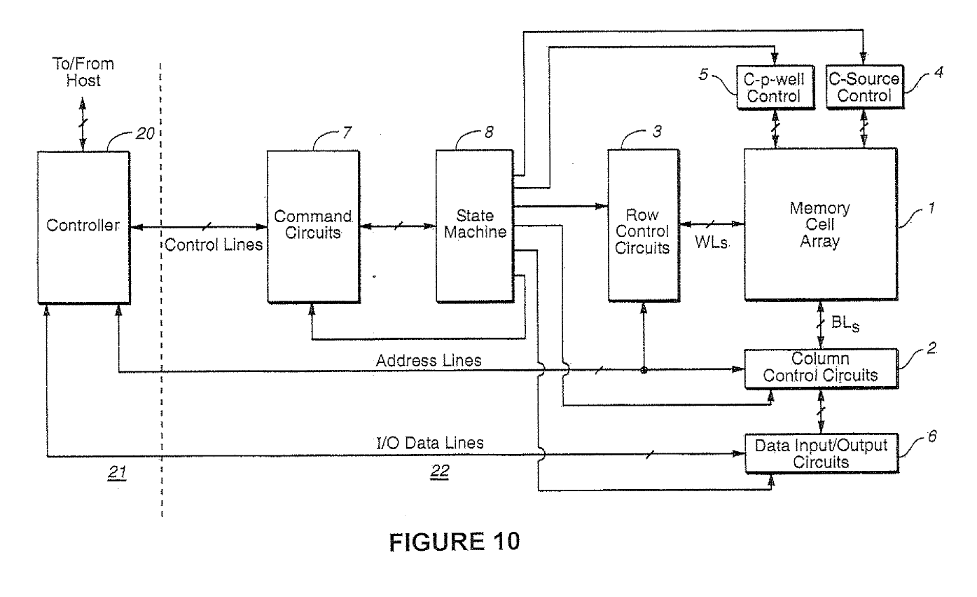

FIG. 10 is a high-level schematic block diagram of a flash memory device. A memory cell array 1 including a plurality of memory cells M arranged in a matrix is controlled by a column control circuit 2, a row control circuit 3, a c-source control circuit 4 and a c-p-well control circuit 5. Column control circuit 2 is connected to bit lines (BL) of memory cell array 1 for reading data stored in the memory cells (M), for determining a state of the memory cells (M) during a writing operation, and for controlling potential levels of the bit lines (BL) to promote the writing or to inhibit the writing. Row control circuit 3 is connected to word lines (WL) to select one of the word lines (WL), to apply read voltages, to apply writing voltages combined with the bit line potential levels controlled by column control circuit 2, and to apply an erase voltage coupled with a voltage of a p-type region on which the memory cells (M) are formed. C-source control circuit 4 controls a common source line connected to the memory cells (M). C-p-well control circuit 5 controls the c-p-well voltage.

The data stored in the memory cells (M) are read out by column control circuit 2 and are output to external I/O lines via an I/O line and a data input/output buffer 6. Program data to be stored in the memory cells are input to data input/output buffer 6 via the external I/O lines, and are transferred to column control circuit 2. The external I/O lines are connected to a controller 20.

Command data for controlling the flash memory device are input to a command interface connected to external control lines which are connected with controller 20. The command data inform the flash memory of what operation is requested. The input command is transferred to a state machine 8 that controls column control circuit 2, row control circuit 3, c-source control circuit 4, c-p-well control circuit 5 and data input/output buffer 6. State machine 8 can output a status data of the flash memory such as READY/BUSY or PASS/FAIL.

Controller 20 is connected or connectable with a host system such as a personal computer, a digital camera, a personal digital assistant. It is the host which initiates commands, such as to store or read data to or from the memory array 1, and provides or receives such data, respectively. Controller 20 converts such commands into command signals that can be interpreted and executed by command circuits 7. Controller 20 also typically contains buffer memory for the user data being written to or read from the memory array. A typical memory device includes one integrated circuit chip 21 that includes controller 20, and one or more integrated circuit chips 22 that each contain a memory array and associated control, input/output and state machine circuits. The trend, of course, is to integrate the memory array and controller circuits of such a device together on one or more integrated circuit chips. The memory device may be embedded as part of the host system, or may be included in a memory card that is removably insertable into a mating socket of host systems. Such a card may include the entire memory device, or the controller and memory array, with associated peripheral circuits, may be provided in separate cards.

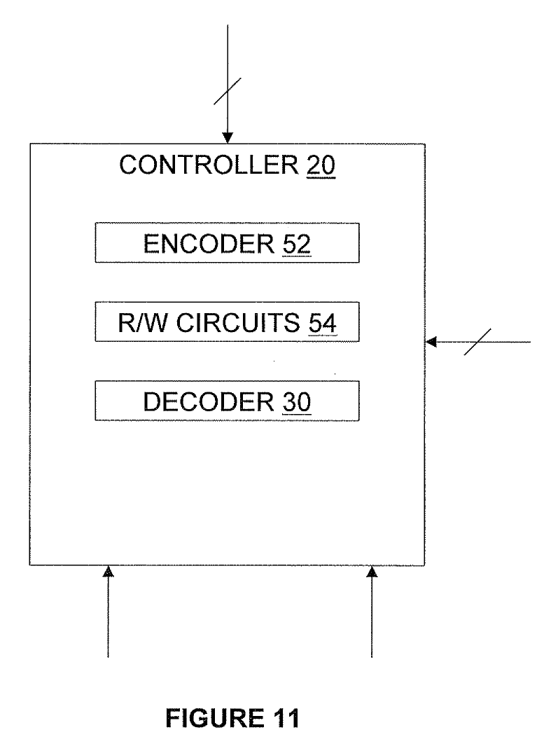

FIG. 11 is an enlarged view of part of FIG. 10, showing that controller 20 includes an encoder 52 for encoding user data received from the host as one or more codewords, circuitry 54 for instructing command circuits 7 to store the codewords (or only the non-punctured bits thereof, if any of the bits of the codewords are punctured bits) in memory cell array 1 and for instructing command circuits 7 to retrieving the stored codewords (or the stored portions thereof in the punctured bit case) from memory cell array 1, and decoder 30 for decoding the representation of the codewords as retrieved by circuitry 54. Alternatively, controller 20 could include decoder 31 instead of decoder 30.

Although the methods and the decoders disclosed herein are intended primarily for use in data storage systems, these methods and decoders also are applicable to communications systems, particularly communications systems that rely on wave propagation through media that strongly attenuate high frequencies. Such communication is inherently slow and noisy. One example of such communication is radio wave communication between shore stations and submerged submarines.

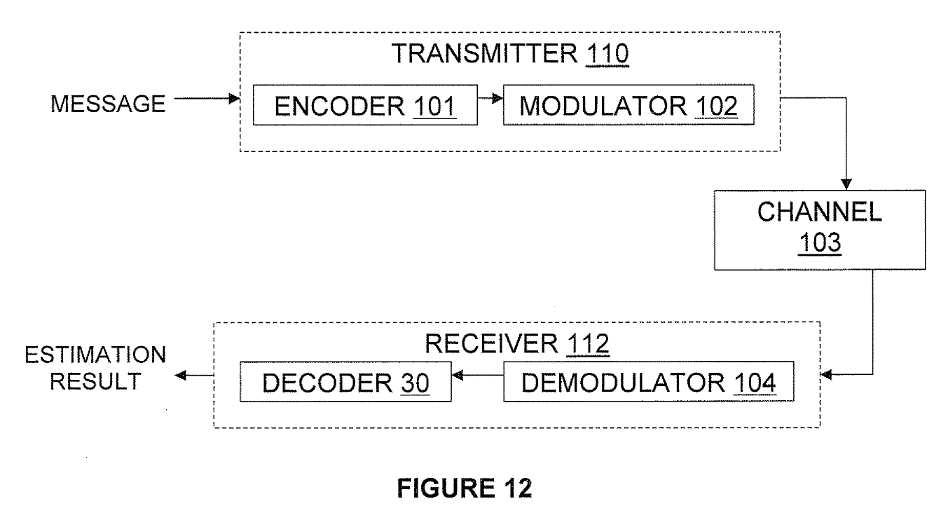

FIG. 12 is a high-level schematic block diagram of a communication system 100 that includes a transmitter 110, a channel 103 and a receiver 112. Transmitter 110 includes an encoder 101 and a modulator 102. Receiver 112 includes a demodulator 104 and decoder 30. Encoder 101 receives a message and generates a corresponding codeword. Modulator 102 subjects the generated codeword to a digital modulation such as BPSK, QPSK or multi-valued QAM and transmits the resulting modulated signal to receiver 12 via channel 103. At receiver 112, demodulator 104 receives the modulated signal from channel 103 and subjects the received modulated signal to a digital demodulation such as BPSK, QPSK or multi-valued QAM. Decoder 30 decodes the resulting representation of the original codeword as described above. Alternatively, receiver 112 could include decoder 31 instead of decoder 30.

Turning now to the issue of trapping sets, there are two types of conventional methods for overcoming trapping sets in LDPC decoding:

1. Avoid trapping sets by designing LDPC codes without trapping sets.

2. Overcome trapping sets by algorithmic means during decoding.

The first type of conventional methods has the following disadvantages:

Since trapping sets are not well defined, and long LDPC codes are quite complex, designing a graph with a low error floor, and proving that the error floor is low, may be a difficult task that requires extensive simulations. Moreover, such an approach may exclude the use of some LDPC codes that exhibit good properties with respect to other aspects, such as implementation complexity in encoding/decoding schemes, decoding speed and flexibility.

As for the second type of conventional methods, using algorithmic methods during decoding for overcoming trapping sets:

Several suggested methods are mentioned in the literature:

1. Averaging.

2. Informed Dynamic Scheduling

3. Identifying the trapping set and designing a custom sum-product Algorithm trying to avoid them.

1. The averaging method uses an update algorithm for the bit values. The updates are based, not only on the results of the preceding iteration, but on averages over the results of a few iterations. Several averaging methods have been suggested including arithmetic averaging, geometric averaging, and a weighted arithmetic geometric average.

2. Informed Dynamic Scheduling. In this method, not all check nodes are updated at each iteration but rather the next check node to be updated is selected based on the current state of the messages in the graph. The check node is selected based on a metric that measures how useful that check node update is to the decoding process.

Both methods can achieve improvement in the error floor, hut the associated complexity of the algorithms is high, since averaging requires storing a history of previous messages, and Informed Dynamic Scheduling incurs high computational complexity.

Methods of the third type require identification of the trapping set and a tailor-made algorithm for each graph, which limit their usage to specific scenarios, especially when multiple LDPC codes are considered in the same application.

According to the innovative method now described, the decoding of a codeword is performed in two phases. During the first phase, conventional decoding is performed along the graph defined by the LDPC code.

If a trapping set is suspected to exist, which prevents the decoding process from converging to a legal codeword (i.e. a codeword satisfying all parity check equations), then the second phase of the decoding is entered. In this phase some of the values associated with the nodes of the graph of the code are modified.

Since existence of a trapping set implies that a small number of bits are failing to converge correctly, the existence of a trapping set may be identified if all but a small number of bits are stable during successive iterations of the decoding, or if a small number of parity check equations fail while all other parity check equations are S satisfied. For example, if only parity check equations within only one sub-graph of a graph that has been partitioned as described above fail, that sub-graph is suspected to be, or to include, a trapping set. Another symptom suggestive of the existence of a trapping set is only one percent or fewer parity check equations failing consistently. For example, that some of the elements of the syndrome H·v′, where v′ is the column vector of estimated bits, are non-zero and are identical in two consecutive iterations, suggests the existence of a trapping set.

Two examples of such modification are as follows:

1. Resetting the values of the check node messages R_{cv} to zero.

2. Truncating the soft values Qᵥ corresponding to bit probabilities, i.e., limiting the magnitudes of the soft values Qᵥ corresponding to bit probabilities to be no more than a predetermined value, typically a value between 10 and 16.

The motivation behind this methodology is that failure to converge due to a small trapping set occurs when the incorrect bits achieved a high probability during the iterative process and the reliability of the incorrect results (contained at the nodes corresponding to parity check equations) is also high. In such a situation, further iterations will not alter the hard decisions (preferably implemented as the sign of the soft values) made on the incorrect bits.

However, if the decoder had started its operation in an initial state in which all bits outside a small trapping set are already at their correct values, then the probability of correctly decoding the codeword is extremely high.

By resetting the values of the messages R_{cv} to zero we revert to a state where all the bits outside the trapping set are correct.

In this situation, messages Q_{vc} and R_{cv} related to bits which are correctly decoded (most of the bits at this stage) quickly build up to high reliability values, while messages related to bits in the trapping set build up more slowly, thus there is a greater influence on the values corresponding the bits in the trapping set from the correct messages. Such a procedure helps in correcting the values of bits in the trapping set.

This procedure adds only minimal complexity to a conventional LDPC decoding algorithm.

In one embodiment, the algorithm performs decoding for a limited number of iterations. Upon failure to converge, the algorithm adds a step for setting certain variables, such as some or all the R_{cv} messages, to zero, and then continues with conventional decoding.

In another embodiment, after performing the limited number of iterations, a truncating operation on several variables, such as some or all of the Qᵥ values, is added, and then the algorithm continues with conventional decoding.

Both algorithms are very simple and of low complexity to implement, moreover they apply to general LDPC graphs, in contrast to the conventional high complexity and tailor based methods.

Truncating the soft values Qᵥ is useful in reaction to a variety of non-convergence criteria and slow convergence criteria, as follows:

1. if a predetermined of elements of the syndrome are non-zero after a pre-determined number of iterations, or after a pre-determined time, or after a pre-determined number of message exchanges. A typical value of the predetermined number of elements is 1.

2. if at most a pre-determined number of elements of the syndrome remain non-zero in two consecutive iterations.

3. if the difference between the numbers of non-zero elements of the syndrome in two consecutive iterations is less than a predetermined limit, suggesting slow convergence.

4. if the Hamming distance between the bit estimates before and after a predetermined number of iterations (typically one iteration) is less than a predetermined limit, suggesting slow convergence.

Decoders 30 and 31 of FIGS. 7A and 7B are modified easily to account for non-convergence and for slow convergence as described above. Specifically, routing layer 44 is modified to detect non-convergence or slow convergence according to the criteria described above, and processors 42 are modified to zero out some or all of the R_{cv} values, and/or to truncate some or all of the Qᵥ values, in response to non-convergence or slow convergence as determined by routing layer 44.

The foregoing has described a limited number of embodiments of methods for decoding a representation of a codeword, of decoders that use these methods, of memories whose controllers include such decoders, and of communication systems whose receivers include such decoders. It will be appreciated that many variations, modifications and other applications of the methods, decoders, memories and systems may be made.

1. A method of decoding a representation of a codeword that encodes K information bits as N>K codeword bits, the method comprising:
(a) importing the representation of the codeword from a channel;
(b) in a plurality of decoding iterations, updating estimates of the codeword bits by steps including, in a graph that includes N bit nodes and N−K check nodes, exchanging messages between the bit nodes and the check nodes; and
(c) if
(i) the decoding has failed to converge according to a predetermined failure criterion, and
(ii) the estimates of the codeword bits satisfy a criterion symptomatic of the graph including a trapping set:
re-setting at least a portion of the messages before continuing the iterations.

2. The method of claim 1, further comprising:
(d) partitioning at least a portion of the graph into a plurality of subgraphs; wherein at least a portion of the exchanging of the messages is effected separately within each subgraph; and
wherein the criterion that is symptomatic of the graph including a trapping set includes failure of the decoding to converge in only one of the subgraphs.

3. The method of claim 1, wherein the criterion that is symptomatic of the graph including a trapping set includes at most about one percent of elements of a syndrome of the estimates being non-zero and constant in two consecutive iterations.

4. The method of claim 1, wherein the re-setting includes setting to zero at least a portion of the messages to be sent from the check nodes.

5. The method of claim 4, wherein the re-setting includes setting to zero all the messages to be sent from the check nodes.

6. The method of claim 1, wherein the re-setting includes truncating at least a portion of the messages to be sent from the bit nodes.

7. The method of claim 6, wherein the re-setting includes truncating all the messages to be sent from the bit nodes.

8. The method of claim 6, wherein the messages are log likelihood ratios and wherein the truncation is to a magnitude of at most between about 10 and about 16.

9. A method of decoding a representation of a codeword that encodes K information bits as N>K codeword bits, the method comprising:
(a) importing the representation of the codeword from a channel;
(b) in a plurality of decoding iterations, updating estimates of the codeword bits by steps including, in a graph that includes N bit nodes and N−K check nodes, exchanging messages between the bit nodes and the check nodes; and
(c) it according to a predetermined failure criterion, the decoding fails to converge, truncating at least a portion of the messages that are sent from the bit nodes before continuing the iterations.

10. The method of claim 9, wherein the predetermined failure criterion includes at least a predetermined number of elements of a syndrome of the estimates being non-zero.

11. The method of claim 10, wherein the predetermined number is one.

12. The method of claim 10, wherein the predetermined failure criterion includes the at least predetermined number of elements of the syndrome being non-zero after a predetermined number of the iterations.

13. The method of claim 10, wherein the predetermined failure criterion includes the at least predetermined number of elements of the syndrome being non-zero after a predetermined time.

14. The method of claim 10, wherein the predetermined failure criterion includes the at least predetermined number of elements of the syndrome being non-zero after a predetermined number of exchanges of the messages.

15. The method of claim 9, wherein the predetermined failure criterion includes at most a predetermined number of elements of a syndrome of the estimates remaining non-zero in two consecutive iterations.

16. The method of claim 9, wherein the predetermined failure criterion includes a difference between numbers of non-zero elements of a syndrome of the estimates after two consecutive iterations being less than a predetermined limit.

17. The method of claim 9, wherein the predetermined failure criterion includes a Hamming distance between the estimates before and after a predetermined number of consecutive iterations being less than a predetermined limit.

18. The method of claim 17, wherein the predetermined number of consecutive iterations is one.

19. The method of claim 9, wherein all the messages that are sent from the bit nodes are truncated.

20. The method of claim 9, wherein the messages are log likelihood ratios and wherein the truncation is to a magnitude of at most between about 10 and about 16.

21. A decoder for decoding a representation of a codeword that encodes K information bits as N>K codeword bits, comprising a processor for decoding the representation of the codeword by executing an algorithm for updating estimates of the codeword by steps including,
(a) in a plurality of decoding iterations, updating estimates of the codeword bits by steps including, in a graph that includes N bit nodes and N−K check nodes, exchanging messages between the bit nodes and the check nodes; and
(b) if
(i) the decoding has failed to converge according to a predetermined failure criterion, and
(ii) the estimates of the codeword bits satisfy a criterion symptomatic of the graph including a trapping set:
re-setting at least a portion of the messages before continuing the iterations.

22. A decoder for decoding a representation of a codeword that encodes K information bits as N>K codeword bits, comprising a processor for decoding the representation of the codeword by executing an algorithm for updating estimates of the codeword by steps including:
(a) in a plurality of decoding iterations, updating estimates of the codeword bits by steps including, in a graph that includes N bit nodes and N−K check nodes, exchanging messages between the bit nodes and the check nodes; and
(b) if, according to a predetermined failure criterion, the decoding fails to converge, truncating at least a portion of the messages that are sent from the bit nodes before continuing the iterations.

23. A memory controller comprising:
(a) an encoder for encoding K information bits as a codeword of N>K codeword bits; and
(b) a decoder including a processor for decoding a representation of the codeword by executing an algorithm for updating estimates of the codeword by steps including:
(i) in a plurality of decoding iterations, updating estimates of the codeword bits by steps including, in a graph that includes N bit nodes and N−K check nodes, exchanging messages between the bit nodes and the check nodes, and
(ii) if
(A) the decoding has failed to converge according to a predetermined failure criterion, and
(B) the estimates of the codeword bits satisfy a criterion symptomatic of the graph including a trapping set:
re-setting at least a portion of the messages before continuing the iterations.

24. The memory controller of claim 23, further comprising:
(c) circuitry for storing at least a portion of the codeword in a main memory and for retrieving a representation of the at least portion of the codeword from the main memory.

25. A memory device comprising;
(a) the memory controller of claim 24; and
(b) the main memory.

26. A memory controller comprising:
(a) an encoder for encoding K information bits as a codeword of N>K codeword bits; and
(b) a decoder including a processor for decoding a representation of the codeword by executing an algorithm for updating estimates of the codeword by steps including:
(i) in a plurality of decoding iterations, updating estimates of the codeword bits by steps including, in a graph that includes N bit nodes and N−K check nodes, exchanging messages between the bit nodes and the check nodes; and
(ii) if, according to a predetermined failure criterion, the decoding fails to converge, truncating at least a portion of the messages that are sent from the bit nodes before continuing the iterations.

27. The memory controller of claim 26, further comprising:
(c) circuitry for storing at least a portion of the codeword in a main memory and for retrieving a representation of the at least portion of the codeword from the main memory.

28. A memory device comprising:
(a) the memory controller of claim 27; and
(b) the main memory.

29. A receiver comprising:
(a) a demodulator for demodulating a message received from a communication channel, thereby producing a representation of a codeword that encodes K information bits as N>K codeword bits; and
(b) a decoder including a processor for decoding the representation of the codeword by executing an algorithm for updating estimates of the codeword by steps including:
(i) in a plurality of decoding iterations, updating estimates of the codeword bits by steps including, in a graph that includes N bit nodes and N−K check nodes, exchanging messages between the bit nodes and the check nodes, and
(ii) if
(A) the decoding has failed to converge according to a predetermined failure criterion, and
(B) the estimates of the codeword bits satisfy a criterion symptomatic of the graph including a trapping set:
re-setting at least a portion of the messages before continuing the iterations.

30. A receiver comprising:
(a) a demodulator for demodulating a message received from a communication channel thereby producing a representation of a codeword that encodes K information bits as N>K codeword bits; and
(b) a decoder including a processor for decoding the representation of the codeword by executing an algorithm for updating estimates of the codeword by steps including:
(i) in a plurality of decoding iterations, updating estimates of the codeword bits by steps including, in a graph that includes N bit nodes and N−K check nodes, exchanging messages between the bit nodes and the check nodes; and
(ii) if, according to a predetermined failure criterion, the decoding fails to converge, truncating at least a portion of the messages that are sent from the bit nodes before continuing the iterations.

31. A communication system for transmitting and receiving a message, comprising:
(a) a transmitter including:
(i) an encoder for encoding K information bits of the message as a codeword of N>K codeword bits, and
(ii) a modulator for transmitting the codeword via a communication channel as a modulated signal; and
(b) a receiver including:
(i) a demodulator for receiving the modulated signal from the communication channel and for demodulating the modulated signal, thereby providing a representation of the codeword, and
(ii) a decoder including a processor for decoding the representation of the codeword by executing an algorithm for updating estimates of the codeword by steps including:
(A) in a plurality of decoding iterations, updating estimates of the codeword bits by steps including, in a graph that includes N bit nodes and N−K check nodes, exchanging messages between the bit nodes and the check nodes, and
(B) if
(I) the decoding has failed to converge according to a predetermined failure criterion, and
(II) the estimates of the codeword bits satisfy a criterion symptomatic of the graph including a trapping set:
re-setting at least a portion of the messages before continuing the iterations.

32. A communication system for transmitting and receiving a message, comprising:
(a) a transmitter including:
(i) an encoder for encoding K information bits of the message as a codeword of N>K codeword bits, and
(ii) a modulator for transmitting the codeword via a communication channel as a modulated signal; and
(b) a receiver including:
(i) a demodulator for receiving the modulated signal from the communication channel and for demodulating the modulated signal, thereby providing a representation of the codeword, and
(ii) a decoder including a processor for decoding the representation of the codeword by executing an algorithm for updating estimates of the codeword by steps including:
(A) in a plurality of decoding iterations, updating estimates of the codeword bits by steps including, in a graph that includes N bit nodes and N−K check nodes, exchanging messages between the bit nodes and the check nodes; and
(B) if, according to a predetermined failure criterion, the decoding fails to converge, truncating at least a portion of the messages that are sent from the bit nodes before continuing the iterations.

33. A method of decoding a representation of a codeword that encodes K information bits as N>K codeword bits, the method comprising:
(a) importing the representation of the codeword from a channel;
(b) providing a parity check matrix having N−K rows and N columns;
(c) in a plurality of decoding iterations, updating estimates of the codeword bits by steps including exchanging messages between the rows and the columns of the matrix; and
(d) if
(i) the decoding has failed to converge according to a predetermined failure criterion, and
(ii) the estimates of the codeword bits satisfy a criterion symptomatic of the parity check matrix including a trapping set:
re-setting at least a portion of the messages before continuing the iterations.

34. A method of decoding a representation of a codeword that encodes K information bits as N>K codeword bits, the method comprising:
(a) importing the representation of the codeword from a channel;
(b) providing a parity check matrix having N−K rows and N columns;
(c) in a plurality of decoding iterations, updating estimates of the codeword bits by steps including exchanging messages between the rows and the columns; and
(d) if, according to a predetermined failure criterion, the decoding fails to converge, truncating at least a portion of the messages that are sent from the columns before continuing the iterations.

35. A decoder for decoding a representation of a codeword that encodes K information bits as N>K codeword bits, comprising a processor for decoding the representation of the codeword by executing an algorithm for updating estimates of the codeword by steps including:
(a) providing a parity check matrix having N−K rows and N columns;
(b) in a plurality of decoding iterations, updating estimates of the codeword bits by steps including exchanging messages between the rows and the columns; and
(c) if
(i) the decoding has failed to converge according to a predetermined failure criterion, and
(ii) the estimates of the codeword bits satisfy a criterion symptomatic of the parity check matrix including a trapping set:
re-setting at least a portion of the messages before continuing the iterations.

36. A decoder for decoding a representation of a codeword that encodes K information bits as N>K codeword bits, comprising a processor for decoding the representation of the codeword by executing an algorithm for updating estimates of the codeword by steps including:
(a) providing a parity check matrix having N−K rows and N columns;
(b) in a plurality of decoding iterations, updating estimates of the codeword bits by steps including exchanging messages between the rows and the columns; and
(c) if, according to a predetermined failure criterion, the decoding fails to converge, truncating at least a portion of the messages that are sent from the columns before continuing the iterations.

37. A memory controller comprising:
(a) an encoder for encoding K information bits as a codeword of N>K codeword bits; and
(b) a decoder including a processor for decoding a representation of the codeword by executing an algorithm for updating estimates of the codeword by steps including:
(i) providing a parity check matrix having N−K rows and N columns;
(ii) in a plurality of decoding iterations, updating estimates of the codeword bits by steps including exchanging messages between the rows and the columns, and
(iii) if
(A) the decoding has failed to converge according to a predetermined failure criterion, and
(B) the estimates of the codeword bits satisfy a criterion symptomatic of the parity check matrix including a trapping set:
re-setting at least a portion of the messages before continuing the iterations.

38. The memory controller of claim 37, further comprising:
(c) circuitry for storing at least a portion of the codeword in a main memory and for retrieving a representation of the at least portion of the codeword from the main memory.

39. A memory device comprising:
(a) the memory controller of claim 38; and
(b) the main memory.

40. A memory controller comprising:
(a) an encoder for encoding K information bits as a codeword of N>K codeword bits; and
(b) a decoder including a processor for decoding a representation of the codeword by executing an algorithm for updating estimates of the codeword by steps including:
(i) providing a parity check matrix having N−K rows and N columns;
(ii) in a plurality of decoding iterations, updating estimates of the codeword bits by steps including exchanging messages between the rows and the columns; and
(iii) if, according to a predetermined failure criterion, the decoding fails to converge, truncating at least a portion of the messages that are sent from the columns before continuing the iterations

41. The memory controller of claim 40, further comprising:
(c) circuitry for storing at least a portion of the codeword in a main memory and for retrieving a representation of the at least portion of the codeword from the main memory.

42. A memory device comprising:
(a) the memory controller of claim 41; and
(b) the main memory.

43. A receiver comprising:
(a) a demodulator for demodulating a message received from a communication channel, thereby producing a representation of a codeword that encodes K information bits as N>K codeword bits; and
(b) a decoder including a processor for decoding the representation of the codeword by executing an algorithm for updating estimates of the codeword by steps including:
(i) providing a parity check matrix having N−K rows and N columns;
(ii) in a plurality of decoding iterations, updating estimates of the codeword bits by steps including exchanging messages between the rows and the columns, and
(iii) if
(A) the decoding has failed to converge according to a predetermined failure criterion, and
(B) the estimates of the codeword bits satisfy a criterion symptomatic of the parity check matrix including a trapping set:
re-setting at least a portion of the messages before continuing the iterations.

44. A receiver comprising:
(a) a demodulator for demodulating a message received from a communication channel, thereby producing a representation of a codeword that encodes K information bits as N>K codeword bits; and
(b) a decoder including a processor for decoding the representation of the codeword by executing an algorithm for updating estimates of the codeword by steps including:
(i) providing a parity check matrix having N−K rows and N columns;
(ii) in a plurality of decoding iterations, updating estimates of the codeword bits by steps including exchanging messages between the rows and the columns; and
(iii) if, according to a predetermined failure criterion, the decoding fails to converge, truncating at least a portion of the messages that are sent from the columns before continuing the iterations.

45. A communication system for transmitting and receiving a message, comprising:
(a) a transmitter including:
(i) an encoder for encoding K information bits of the message as a codeword of N>K codeword bits, and
(ii) a modulator for transmitting the codeword via a communication channel as a modulated signal; and
(b) a receiver including:
(i) a demodulator for receiving the modulated signal from the communication channel and for demodulating the modulated signal, thereby providing a representation of the codeword, and
(ii) a decoder including a processor for decoding the representation of the codeword by executing an algorithm for updating estimates of the codeword by steps including:
(A) providing a parity check matrix having N−K rows and N columns;
(B) in a plurality of decoding iterations, updating estimates of the codeword bits by steps including exchanging messages between the rows and the columns, and
(C) if
(I) the decoding has failed to converge according to a predetermined failure criterion, and
(II) the estimates of the codeword bits satisfy a criterion symptomatic of the parity check matrix including a trapping set:
re-setting at least a portion of the messages before continuing the iterations.

46. A communication system for transmitting and receiving a message, comprising:
(a) a transmitter including:
(i) an encoder for encoding K information bits of the message as a codeword of N>K codeword bits, and
(ii) a modulator for transmitting the codeword via a communication channel as a modulated signal; and
(b) a receiver including;
(i) a demodulator for receiving the modulated signal from the communication channel and for demodulating the modulated signal, thereby providing a representation of the codeword, and
(ii) a decoder including a processor for decoding the representation of the codeword by executing an algorithm for updating estimates of the codeword by steps including:
(A) providing a parity check matrix having N−K rows and N columns;
(B) in a plurality of decoding iterations, updating estimates of the codeword bits by steps including exchanging messages between the rows and the columns; and
(C) if, according to a predetermined failure criterion, the decoding fails to converge, truncating at least a portion of the messages that are sent from the columns before continuing the iterations.
